(19) United States
(12) Patent Application Publication
(10) Pub. No.: US 2016/0204371 A1
(43) Pub. Date: Jul. 14, 2016

(54) ORGANIC LIGHT-EMITTING DEVICE AND DISPLAY APPARATUS INCLUDING THE SAME

(71) Applicant: Samsung Display Co., Ltd., Yongin-si (KR)

(72) Inventors: Hyoyeon KIM, Hwaseong-si (KR); Hye-yeon Shim, Seoul (KR); Byeongwook Yoo, Hwaseong-si (KR)

(21) Appl. No.: 14/949,084

(22) Filed: Nov. 23, 2015

(30) Foreign Application Priority Data
Jan. 13, 2015 (KR) 10-2015-0006048

(51) Int. Cl. H01L 51/50; H01L 27/32

(52) U.S. Cl. CPC H01L 51/5016; H01L 51/5072; H01L 27/3211; H01L 51/5206

(57) ABSTRACT

An organic light-emitting device including: a first electrode; a light-emitting layer disposed on the first electrode; a second electrode disposed on the light-emitting layer; and an electron transport region disposed between the light-emitting layer and the second electrode. The light-emitting layer includes a first doped region and a second doped region disposed between the first doped region and the electron transport region. The first doped region includes a host material and a dopant material, and the second doped region includes the host material, the dopant material, and an electron transport material. The second doped region includes the host material, the doped material, and an electron transport material.

### CROSS-REFERENCE TO RELATED APPLICATION

This application claims priority from and the benefit of Korean Patent Application No. 10-2015-0006048, filed on Jan. 13, 2015, which is hereby incorporated by reference for all purposes as if fully set forth herein.

### BACKGROUND

1. Field

Exemplary embodiments relate to an organic light-emitting device and a display apparatus having the same. More particularly, exemplary embodiments relate to an organic light-emitting device having improved luminous properties so as to be more suitable for display apparatuses, and a display apparatus having improved display quality by including the same.

2. Discussion of the Background

An organic electroluminescent display apparatus is one kind of flat display apparatuses currently in use, and is gradually replacing liquid crystal display apparatuses that have been widely used for many years. Because the organic electroluminescent display apparatus generates its own light to display an image, unlike the liquid crystal display apparatus, the organic electroluminescent display apparatus does not need a backlight unit generating light as an element thereof. Therefore, because the organic electroluminescent display apparatus has not only an advantage in reducing the thickness thereof compared to the liquid crystal display apparatus, but also excellent response characteristics, the available range of the organic electroluminescent display apparatus considered as a next generation display apparatus is gradually increasing.

Generally, the organic electroluminescent display apparatus includes an organic light-emitting device, and the organic light-emitting device includes an anode electrode, a cathode electrode, a hole injection layer interposed between the two electrodes, a hole transport layer, an organic light-emitting layer, and a hole injection layer. Holes and electrons are provided to the organic light-emitting layer through the anode electrode and the cathode electrode, respectively. Therefore, the electrons and holes are recombined with each other in the organic light-emitting layer to generate excitons, and the excitons transit from an excited state to a ground state to generate energy, thereby generating light from the organic light-emitting layer.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments provide an organic light-emitting device having improved luminous properties so as to be more suitably applied to display apparatuses.

Exemplary embodiments also provide a display apparatus having improved display quality by including the organic light-emitting device having improved luminous properties.

Additional aspects will be set forth in the detailed description which follows, and, in part, will be apparent from the disclosure, or may be learned by practice of the inventive concept.

An exemplary embodiment of the present invention discloses an organic light-emitting device including: a first electrode; a light-emitting layer disposed on the first electrode; a second electrode disposed on the light-emitting layer; and an electron transport region disposed between the light-emitting layer and the second electrode. The light-emitting layer includes a first doped region and a second doped region disposed between the first doped region and the electron transport region. The first doped region includes a host material and a dopant material, and the second doped region includes the host material, the dopant material, and an electron transport material.

An exemplary embodiment of the present invention also discloses a display apparatus including: a base substrate having a plurality of pixel regions; and a first organic light-emitting device disposed on a first one of the pixel regions. The first organic light-emitting device includes: a first electrode disposed on the base substrate; a first light-emitting layer disposed on the first electrode; a second electrode disposed on the first light-emitting layer; and an electron transport region disposed between the first light-emitting layer and the second electrode. The first light-emitting layer includes a first doped region and a second doped region disposed between the first doped region and the electron transport region. The first doped region includes a host material and a dopant material, and the second doped region includes the host material, the dopant material, and an electron transport material.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a cross-sectional view illustrating an organic light-emitting device according to an exemplary embodiment.

FIG. 2 is a cross-sectional view illustrating an organic light-emitting device according to another exemplary embodiment.

FIGS. 3 and 4 are cross-sectional views illustrating a display apparatus including the organic light-emitting device illustrated in FIG. 1.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

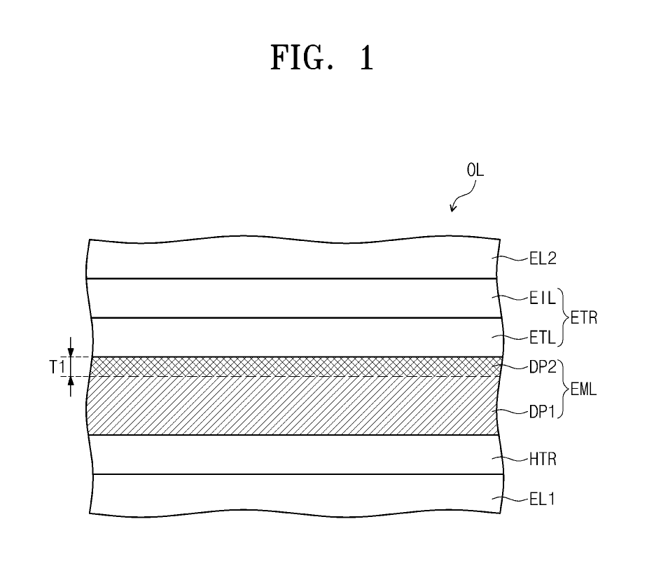

FIG. 1 is a cross-sectional view illustrating an organic light-emitting device OL according to an exemplary embodiment.

Referring to FIG. 1, an organic light-emitting device OL includes a first electrode EL1, a second electrode EL2, a light-emitting layer EML, a hole transport region HTR (or a hole control layer), and an electron transport region ETR (or an electron control layer).

The first electrode EU has conductivity. In the organic light-emitting device OL according to this exemplary embodiment, the first electrode EU may function as an anode, and be a transparent electrode, a semi-transparent electrode, or a reflective electrode.

When the first electrode EU is a transparent electrode, the first electrode EU may include a transparent metal oxide. For example, the first electrode EL1 may include at least one selected from indium tin oxide (ITO), indium zinc oxide (IZO), zinc oxide (ZnO), and indium tin zinc oxide (ITZO).

When the first electrode EU is a semi-transparent electrode or a reflective electrode, the first electrode EU may include at least one of metals such as Ag, Mg, Al, Pt, Pd, Au, Ni, Nd, Ir, and Cr.

The hole transport region HTR is disposed on the first electrode EL1. The hole transport region HTR may have a single-layered structure formed of a single material, or a multi-layered structure formed of different materials.

The hole transport region HTR may include a hole injection layer and a hole transport layer. When the hole transport region HTR includes a hole injection layer, the hole transport region HTR may include a phthalocyanine compound, such as copper phthalocyanine; or N,N′-diphenyl-N,N′-bis-[4-(phenyl-m-tolyl-amino)-phenyl]-biphenyl-4,4′-diamine (DNTPD), 4,4′,4″-tris(3-methylphenylphenylamino)triphenylamine (m-MTDATA), 4,4′4″-tris(N,N-diphenylamino)triphenylamine (TDATA), 4,4′,4″-tris{N,-(2-naphthyl)-N-phenylamino}-triphenylamine (2TNATA), poly(3,4-ethylenedioxythiophene)/poly(4-styrenesulfonate) (PEDOT/PSS), a polyaniline/dodecylbenzenesulfonic acid (PANI/DBSA), a polyaniline/camphor sulfonic acid (PANI/CSA), or polyaniline/poly(4-styrenesulfonate) (PANI/PSS). As described above, the materials of the hole transport region HTR are exemplified, but the inventive concept is not limited to the aforementioned materials of the hole transport region HTR.

When the hole transport region HTR includes a hole transport layer, the hole transport region HTR may include carbazole derivatives such as N-phenyl carbazole or polyvinyl carbazole, a fluorine-based derivative, triphenylamine-based derivatives such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(1-naphthyl)-N,N′-diphenylbenzidine (NPB), or 4,4′-cyclohexylidene bis[N,N-bis(4-methylphenyl)benzenamine (TAPC). As described above, the materials of the hole transport region HTR are exemplified, but the inventive concept is not limited to the aforementioned materials of the hole transport region HTR.

The electron transport region ETR may be disposed between the light-emitting layer EML and the second electrode EL2. Electrons injected from the second electrode EL2 may reach the light-emitting layer 100 via the electron transport region ETR.

In this exemplary embodiment, the electron transport region ETR may include an electron transport layer ETL and an electron injection layer EIL.

The electron transport layer ETL includes an electron transport material. In this exemplary embodiment, the electron transport material may include tris(8-hydroxyquinolinato)aluminum (Alq3), 1,3,5-Tri(1-phenyl-1H-benzo[d]imidazol-2-yl)phenyl (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-naphthalen-1-yl)-3,5-diphenyl-4H-1,2,4-triazolen (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate) (Bebq2), 9,10-di(naphthalene-2-yl)anthracene (ADN), and a mixture thereof. As described above, the electron transport materials are exemplified, but the inventive concept is not limited to the aforementioned electron transport materials.

The electron injection layer EIL may include may include LiF, lithium quinolate (LiQ), Li₂O, BaO, NaCl, a lanthanide group metal such as CsF, or Yb, or metal halide such as RbCl or RbI. In another exemplary embodiment, the electron injection layer EIL may include a material into which an insulating organo metal salt is mixed. In this case, the organo metal salt may have an energy band gap of about 4 eV or more. For example, the organo metal salt may include at least one selected from metal acetate, metal benzoate, metal acetoacetate, metal acetylacetonate, or metal stearate. As described above, the electron injection materials are exemplified, but the inventive concept is not limited to the aforementioned electron injection materials.

The light-emitting layer EML is disposed between the hole transport region HTR and the electron transport region ETR.

In this exemplary embodiment, the light-emitting layer EML includes a first doped region DP1 and a second doped region DP2. The first doped region DP1 is disposed between the hole transport region HTR and the second doped region DP2, and contacts the hole transport region HTR. Also, the second doped region DP2 is disposed between the first doped region DP1 and the electron transport region ETR, and contacts the electron transport region ETR.

In this exemplary embodiment, the first doped region DP1 includes a host material and a dopant material. Also, the second doped region DP2 includes the host material and the dopant material, and may further include the electron transport material exemplified as the material of the electron transport region ETR. That is, the light-emitting layer EML includes the host material, and the dopant material is doped into the host material in the first doped region DP1. Also, the electron transport material as well as the dopant material is further doped into the host material in the second doped region DP2 of the light-emitting layer EML.

In this exemplary embodiment, the electron transport region ETR and the second doped region DP2 may include the same material. In another exemplary embodiment, the electron transport region ETR and the second doped region DP2 may include the electron transport material as exemplified above, and include different electron transport materials.

Meanwhile, when the light-emitting layer EML includes the second doped region DP2, driving characteristics of the organic light-emitting device OL may be controlled by the second doped region DP2 as follows.

When the organic light-emitting device OL is driven at low gradation or at low current, the mobility of electrons that are injected from the second electrode EL2 and pass through the second doped region DP2 is reduced, and as a result, the luminance efficiency of the organic light-emitting device OL may be reduced. However, when the organic light-emitting device OL is driven at high gradation or at high current, electrons injected through the second electrode EL2 may generate a tunneling effect with respect to the second doped region DP2. Therefore, when the organic light-emitting device OL is driven at high gradation, the mobility of electrons is not reduced by the second doped region DP2 enough to reduce the luminance efficiency of the organic light-emitting diode OL.

That is, as the organic light-emitting device OL includes the light-emitting layer EML defining the second doped region DP2, the luminance efficiency of the organic light-emitting device OL is selectively decreased when driven at only low gradation of low gradation and high gradation. Therefore, according to the low gradation drive, the luminance efficiency of the organic light-emitting device OL may be controlled by using the second doped region DP2.

In the present exemplary embodiment, as a thickness T1 of the second doped region DP2 is increased, the luminance efficiency of the organic light-emitting device OL may be decreased. Also, as a doping concentration of the electron transport material is increased, the luminance efficiency of the organic light-emitting device OL may be decreased.

Therefore, when a display apparatus including other organic light-emitting devices in addition to the organic light-emitting device OL is realized at low gradation, and it is assumed that the organic light-emitting device OL has first luminance efficiency and average luminance efficiency of the organic light-emitting devices is defined as second luminance efficiency, a difference between the first luminance efficiency and the second luminance efficiency may be minimized by reducing the first luminance efficiency.

In contrast to the inventive concept of the disclosed embodiments, when the difference between the first luminance efficiency and the second luminance efficiency is large in driving at the low gradation, a balance of intensities of light emitted from the organic light-emitting device OL and light emitted from the organic light-emitting devices may be collapsed, and as a result, a spot may be displayed on a display region of the display apparatus, thereby deteriorating the display quality of the display apparatus. However, as in the present exemplary embodiment, when the difference between the first luminance efficiency and the second luminance efficiency is minimized by applying the second doped region DP2 to the organic light-emitting layer EML, any spot generated on the display region may be minimized, thereby improving the display quality of the display apparatus.

In the present exemplary embodiment, the light-emitting layer EML may include a phosphorescent material emitting red light, and in this case, the luminance efficiency of the organic light-emitting device OL may be greater than those of the organic light-emitting devices including different light-emitting layers. Therefore, it may be desirable that the luminance efficiency of the organic light-emitting device OL according to the low gradation drive be reduced by applying the second doped region DP2 to the organic light-emitting layer EML.

In the present exemplary embodiment, a minimum value of the thickness T of the second doped region DP2 may be about 100 angstroms. When the thickness T1 is less than 100 angstroms, the luminance efficiency of the organic light-emitting device OL according to the low gradation drive may be somewhat reduced.

The inventive concept is not limited to the host material and the dopant material of the light-emitting layer EML, but the host material and the dopant material may be exemplified as follows.

In the present exemplary embodiment, the host material may include a material such as tris(8-quinolinolato) aluminum (Alq3), 4,4′-bis (N-carbazolyl)-1,1′-biphenyl (CBP), poly(n-vinylcarbazole) (PVK), 9,10-di(naphthalene-2-yl)anthracene (ADN), 4,4′,4″-tris(carbazol-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyrylarylene (DSA), 4,4′-bis(9-carbazolyl)-2,2′-dimethyl-biphenyl (CDBP), or 2-Methyl-9,10-bis(naphthalen-2-yl)anthracene (MADN).

When the light-emitting layer EML emits red light, the light-emitting layer EML may include, for example, PBD:Eu(DBM)3(Phen)(tris(dibenzoylmethanato)phenanthoroline europium) or perylene. Also, when the light-emitting layer EML emits red light, the dopant material of the light-emitting layer EML may include, for example, metal complexes such as bis(1-phenylisoquinoline)acetylacetonate iridium (PIQIr(acac)), bis(1-phenylquinoline)acetylacetonate iridium (PQIr(acac)), tris(1-phenylquinoline)iridium (PQIr), and octaethylporphyrin platinum (PtOEP), or an organometallic complex.

When the light-emitting layer EML emits green light, the light-emitting layer EML may include a florescent material that includes, for example, tris(8-hydroxyquinolino)aluminum (Alq3). Also, when the light-emitting layer EML emits green light, the dopant material of the light-emitting layer EML may include, for example, a metal complex such as fac-tris(2-phenylpyridine)iridium (Ir(ppy)3), or an organometallic complex.

When the light-emitting layer EML emits blue light, the light-emitting layer EML may include a florescent material that includes any one selected from the group consisting of, for example, spiro-DPVBi, spiro-6P, distyryl-benzene (DSB), distyryl-arylene (DSA), a polyfluorene (PFO)-based polymer, and a poly(p-phenylene vinylene) (PPV)-based polymer. When the light-emitting layer EML emits blue light, the dopant material of the light-emitting layer EML may include, for example, a metal complex such as (4,6-F2ppy)2Irpic, or an organometallic complex.

The second electrode EL2 may be disposed on the electron transport region ETR. The second electrode EL2 may function as a cathode electrode in the organic light-emitting device OL.

The second electrode EL2 may have a single-layered structure formed of a single material. Also, the second electrode EL2 may have a multi-layered structure formed of different materials, and in this case, may have a structure in which a layer including a reflective material and a layer including a transparent material are stacked.

When the second electrode EL2 is a transparent electrode, the second electrode EL2 may include at least one selected from Li, Ca, LiF, Al, Mg, BaF, Ba, and Ag.

When the second electrode EL2 is a semi-transparent electrode or a reflective electrode, the second electrode EL2 may include a structure in which a layer including at least one selected from of Ag, Mg, Al, Pt, Pd, Au, Ni, Nd, Ir, Cr, Li, Ca, LiF, Ca, Al, Mo, and Ti, and a transparent conductive layer such as indium tin oxide (ITO), indium zinc oxide (IZO), zinc oxide (ZnO), or indium tin zinc oxide (ITZO) are stacked.

The second electrode EL2 may include an auxiliary electrode (not shown). The auxiliary electrode may include metal oxides, such as indium tin oxide (ITO), indium zinc oxide (IZO), zinc oxide (ZnO), and tin zinc oxide (ITZO), or a metal such as Mo and Ti.

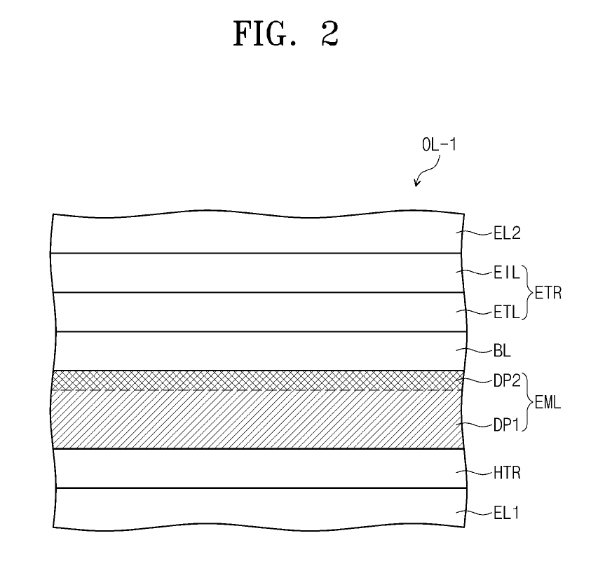

FIG. 2 is a cross-sectional view illustrating an organic light-emitting device OL according to an exemplary embodiment. In describing FIG. 2, the same reference numbers are used with respect to elements described above, and a description with respect to the elements will be omitted.

In comparison between the organic light-emitting device (OL of FIG. 1) illustrated in FIG. 1 and the organic light-emitting device OL-1 illustrated in FIG. 2, the organic light-emitting layer OL-1 further includes a buffer layer BL.

The buffer layer BL is disposed between the light-emitting layer EML and the electron transport region ETR, and may have a lowest unoccupied molecular orbital (LUMO) energy level higher than that of the electron transport region ETR.

The buffer layer BL may reduce the mobility of electrons inflowing from the second electrode EL2 to the light-emitting layer EML. Therefore, when the organic light-emitting device OL-1 is driven at low gradation, the luminance efficiency of the organic light-emitting device OL-1 may be reduced by the buffer layer BL and the second doped region DP2 of the light-emitting layer EML. Accordingly, as described with reference to FIG. 1, a balance of intensities of light emitted from the organic light-emitting device OL-1 and light emitted from the other organic light-emitting devices may be easily maintained, thereby improving the display quality of the display apparatus.

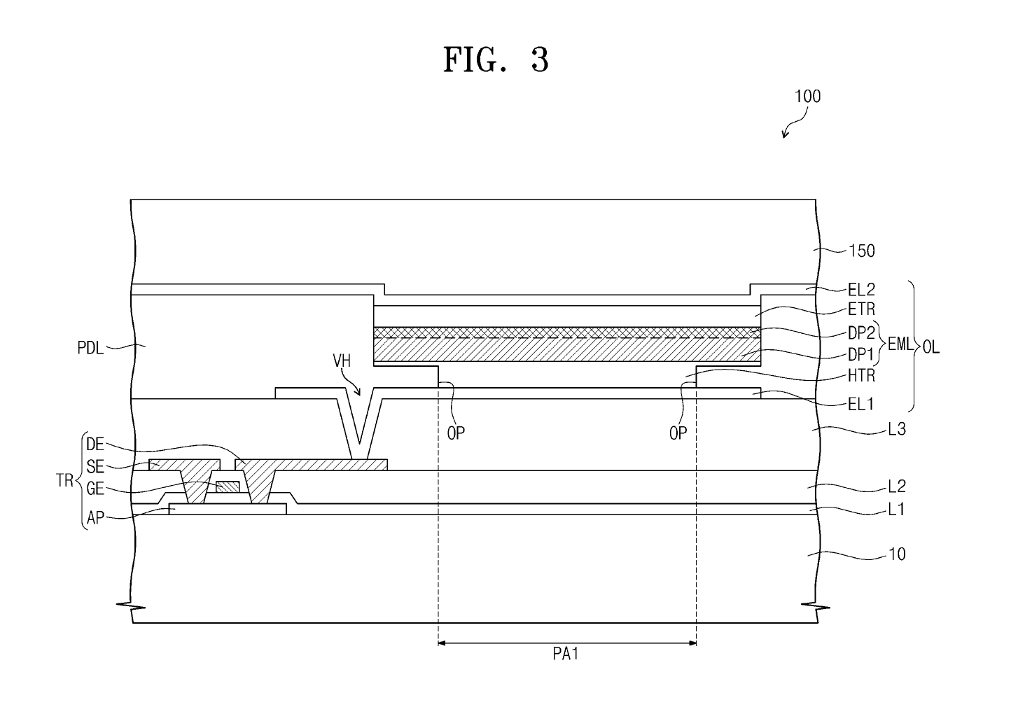

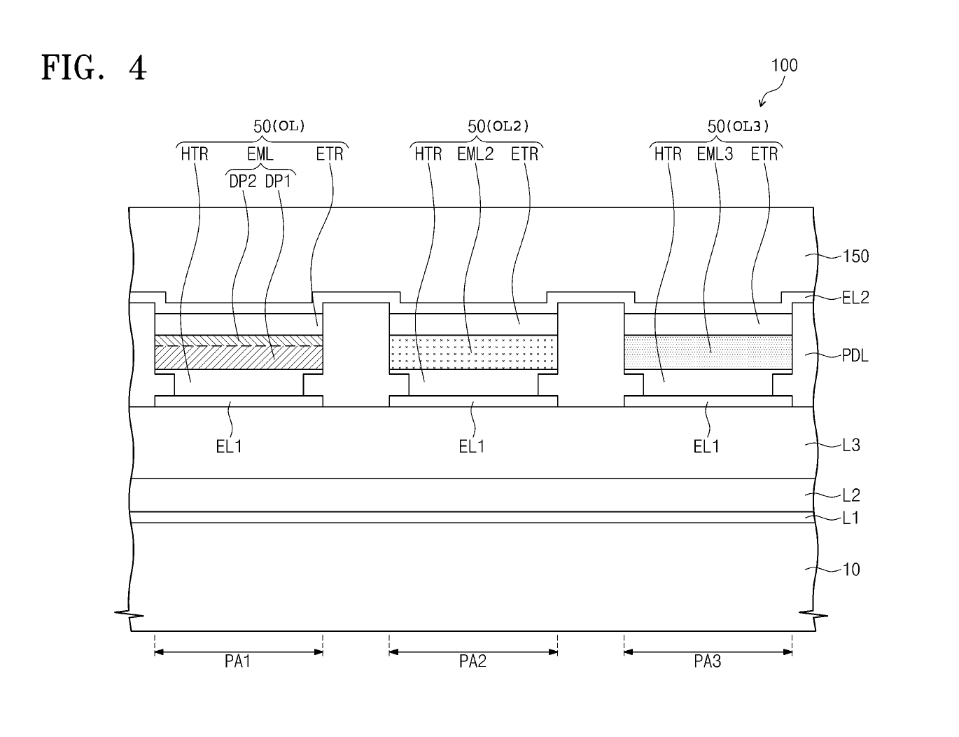

FIGS. 3 and 4 are cross-sectional views illustrating a display apparatus including an organic light-emitting device illustrated in FIG. 1. In describing FIGS. 3 and 4, the same reference numbers are used with respect to elements described above, and a description with respect to the elements will be omitted.

Referring to FIGS. 3 and 4, a display apparatus 100 includes a base substrate 10, organic light-emitting devices 50 disposed on the base substrate 10, and a driving transistor TR electrically is connected to each of the organic light-emitting devices 50.

A first pixel region PA1, a second pixel region PA2, and a third pixel region PA3 are defined on the base substrate 10, and the organic light-emitting devices 50 are disposed so as to each correspond to the first to third pixel regions PA1, PA2, and PA3.

The organic light-emitting device OL of the organic light-emitting devices 50, which is disposed on the first pixel region PA1, has the same structure as the organic light-emitting device (OL of FIG. 1) described above with reference to FIG. 1.

The driving transistor TR is disposed on the base substrate 10. The driving transistor TR is electrically connected to a first electrode EL1 of the organic light-emitting device OL to provide a switching function for the power signal supplied to the first electrode EL1.

The driving transistor TR includes a gate electrode GE, an active pattern AP, a source electrode SE, and a drain electrode DE. The source electrode SE is electrically connected to the power line (not show) transmitting the power signal, and the drain electrode DE is electrically connected to the first electrode EL1. Accordingly, when the driving transistor TR is turned on, the power signal travelling along the power line may be supplied to the first electrode EL1 through the driving transistor TR.

A gate insulation film L1 covers the active pattern AP to insulate the gate electrode GE and the active pattern AP from each other, and an interlayer insulating film L2 covers the gate electrode GE to insulate the gate source and drain electrodes SE and DE from the gate electrode GE. Also, a cover film L3 covers the driving transistor TR, and a via hole VH is formed in the cover film L3. Therefore, the first electrode EL1 disposed on the cover film L3 may be electrically connected to the first electrode EL1 through the via hole VH.

A pixel defining film PDL is disposed on the first electrode EL1, and an opening OP is formed in the pixel defining film PDL so as to correspond to the first pixel region PA1.

An encapsulating layer 150 is disposed on the second electrode EL2 and the pixel defining film PDL to cover the organic light-emitting devices 50. The encapsulating layer 150 may have a single layered-structure or a multi-layered structure. When the encapsulating layer 150 has the multi-layered structure, the encapsulating layer 150 may include a plurality of organic layers and a plurality of inorganic layers that are alternately and repeatedly stacked upon each other.

The organic light-emitting device OL is disposed on the first pixel region PAL In the present exemplary embodiment, the organic light-emitting device OL may output green light, and the light-emitting layer EML may include a fluorescent material or a phosphorescent material.

In the organic light-emitting devices 50, a second organic light-emitting device OL2 disposed on the second pixel region PA2 is also defined. In addition, in the present exemplary embodiment, the second organic light-emitting device OL2 may include may include a second light-emitting layer EML2 emitting red light. The second light-emitting layer EML2 may include the host material and the dopant material described above with reference to FIG. 1.

In the organic light-emitting devices 50, a third organic light-emitting device OL3 disposed on the third pixel region PA3 is also defined. In addition, in the present exemplary embodiment, the third organic light-emitting device OL3 may include a third light-emitting layer EML3 emitting blue. The third light-emitting layer EML3 may include the host material and the dopant material described above with reference to FIG. 1.

In the present exemplary embodiment, as described above with reference to FIG. 1, the organic light-emitting device OL includes the light-emitting layer EML having the first and second doped regions DP1 and DP2. In addition, the second doped region DP2 includes a host material, a dopant material, and an electron transport material. Also, each of the second and third light-emitting layers EML2 and EML3 includes a host material and a dopant material, and does not include an electron transport material.

Therefore, the luminance efficiency of the organic light-emitting device OL in each of the organic light-emitting devices 50 disposed on the first pixel region PA1 may be selectively reduced in driving the organic light-emitting devices 50 at low gradation. As a result, the luminance efficiency of the organic light-emitting device OL may be reduced, so the luminance efficiency difference between the organic light-emitting devices 50 may be easily minimized, thereby preventing a spot from occurring on the display region of the display apparatus 100.

According to exemplary embodiments of the inventive concept, the luminance efficiency of an organic light-emitting device may be easily adjusted by adjusting a thickness of a doped region of a light-emitting layer, which includes a host material, a dopant material, and an electron transport material. Therefore, in driving a display device including organic light-emitting devices at low gradation, a luminance difference between the organic light-emitting devices may be minimized, and as a result, a balance between light intensities emitted from the organic light-emitting devices is maintained, thereby improving the display quality of the display apparatus.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. An organic light-emitting device comprising:
a first electrode;
a light-emitting layer disposed on the first electrode;
a second electrode disposed on the light-emitting layer; and
an electron transport region disposed between the light-emitting layer and the second electrode,
wherein:
the light-emitting layer comprises a first doped region and a second doped region disposed between the first doped region and the electron transport region; and
the first doped region comprises a host material and a dopant material, and the second doped region comprises the host material, the dopant material, and an electron transport material.

2. The organic light-emitting device of claim 1, wherein the light-emitting layer is configured to emit green light.

3. The organic light-emitting device of claim 2, wherein the dopant material comprises a phosphorescent material.

4. The organic light-emitting device of claim 1, wherein the second doped region contacts the electron transport region.

5. The organic light-emitting device of claim 1, further comprising a buffer layer disposed between the light-emitting layer and the electron transport layer, wherein the buffer layer has a lowest unoccupied molecular orbital (LUMO) energy level higher than that of the electron transport region.

6. The organic light-emitting device of claim 1, wherein the electron transport region comprises the same material as the electron transport material.

7. A display apparatus comprising:
a base substrate comprising a plurality of pixel regions; and
a first organic light-emitting device disposed on a first pixel region of the plurality of pixel regions,
wherein;
the first organic light-emitting device comprises:
a first electrode disposed on the base substrate;
a first light-emitting layer disposed on the first electrode;
a second electrode disposed on the first light-emitting layer; and
an electron transport region disposed between the first light-emitting layer and the second electrode;
the first light-emitting layer comprises a first doped region and a second doped region disposed between the first doped region and the electron transport region; and
the first doped region comprises a host material and a dopant material, and the second doped region comprises the host material, the dopant material, and an electron transport material.

8. The display apparatus of claim 7, wherein the first light-emitting layer is configured to emit green light.

9. The display apparatus of claim 8, wherein the dopant material comprises a phosphorescent material.

10. The display apparatus of claim 7, wherein the second doped region contacts the electron transport region.

11. The display apparatus of claim 11, further comprising a buffer layer disposed between the first light-emitting layer and the electron transport layer,
wherein the buffer layer has a lowest unoccupied molecular orbital (LUMO) energy level higher than that of the electron transport region.

12. The display apparatus of claim 7, further comprising:
a second organic light-emitting device disposed on a second pixel region of the plurality of pixel regions, the second organic light-emitting device comprising a second light-emitting layer configured to emit red light; and
a third organic light-emitting device disposed on a third pixel region of the plurality of pixel regions, the third organic light-emitting device comprising a third light-emitting layer configured to emit blue light,
wherein each of the second and third light-emitting layers does not comprise the electron transport material.

13. The display apparatus of claim 7, wherein the electron transport region comprises the same material as the electron transport material.
